(19) United States
(12) Patent Application Publication
(10) Pub. No.: US 2013/0299937 A1
(43) Pub. Date: Nov. 14, 2013

(54) METHOD AND APPARATUS FOR ULTRA-LOW CONTACT RESISTANCE FOR SEMICONDUCTOR CHANNEL N-FET

(71) Applicant: Applied Materials, Inc., Santa Clara, CA (US)

(72) Inventor: Khaled AHMED, Anaheim, CA (US)

(73) Assignee: Applied Materials, Inc., Santa Clara, CA (US)

(21) Appl. No.: 13/871,315

(22) Filed: Apr. 26, 2013

Related U.S. Application Data
(60) Provisional application No. 61/638,869, filed on Apr. 26, 2012.

(51) Int. Cl. H01L 29/47; H01L 29/40

(52) U.S. Cl. CPC H01L 29/47; H01L 29/401
USPC 257/475; 438/549

(57) ABSTRACT

A method and apparatus for reducing external series resistance (Rₑₓₜ) has been becoming a more dominant component of the total series resistance between the MOSFET source and drain. A significant part of Rₑₓₜ (25-35%) comes from the interface resistance (R_{C}) between the metal (silicide) and source/drain (S/D) silicon diffusion regions. R_{C} is determined by the specific contact resistivity (ρ_{c}) at the silicide/silicon interface, the S/D silicon sheet resistivity at the silicide/silicon interface (RS/D), and the contact length (L_{C}). The L_{C} has been and will be decreasing by about 30% from one CMOS technology node to the next, resulting in increased R_{C} and Rₑₓₜ. To maintain or reduce R_{C} with respect to state-of-the-art value, one must reduce ρ_{c}. This may be accomplished using a metal-dopant alloy having a dopant material that can diffuse into the semiconductor layer during annealing to provide contact and ultralow resistance at the interface.

### CROSS-REFERENCE TO RELATED APPLICATION

This application claims benefit of U.S. Provisional Patent Application Ser. No. 61/638,869, filed Apr. 26, 2012, which is incorporated herein by reference.

### BACKGROUND OF THE INVENTION

1. Field of the Invention

Embodiments generally relate to transistors in MOSFET devices which can be represented by three resistors.

2. Description of the Related Art

MOSFET devices have a channel which can be controlled from outside voltage and the channel resistance known as “R channels” can be decreased by applying a voltage on the gate in the device. The channel resistance should be as small as possible when the transistor is on in the “on” state. MOSFET devices also have a parasitic resistance referred to as “R source” and “R drain”. These are external resistances and need to be low in comparison to the channel resistance, i.e. ideally “R source” plus “R drain” is 20% or less of “R channel.”

As devices are scaled down, these resistances rapidly become larger values, which degrades the performance of the integrated circuit (IC). In a transistor there is a source region and a drain region, and then a contact hole is made to deposit a contact between these regions to pull out the current. In the current generation of devices, the contact hole is 40 nm in diameter, in the future it will need to be much smaller, e.g., 10 nm.

The resistance of the two external resistors should be reduced as much as possible. As the dimensions shrink, the primary way to reduce this component is by changing the resistance at the interface between the metal, that acts as a conduit to take current out, and the semiconductor substrate.

The best way to reduce this resistance, which may be referred to as “interface resistance,” is by increasing the doping concentration at the channel contact region of the semiconductor. The semiconductor needs to be highly doped and in contact with the metal. There are various ways of increasing doping concentration in the semiconductor. One way is on implantation, but ion implantation then also causes problems. For example, when the channel contact is very narrow trying to perform on implantation through this small hole (narrow space) is difficult.

### SUMMARY OF THE INVENTION

The present invention generally relates to a MOSFET having external contact resistance (ρ_{C}) across a metal/semiconductor interface, the MOSFET comprising a first semiconductor substrate upon which a metal-dopant alloy layer has been deposited and annealed, wherein a metal of the metal-dopant alloy is chosen from the group comprising Ni, Pd, and Pt and a dopant material is chosen from the group comprising P, As, and Sb. A concentration of dopant material in the semiconductor substrate directly adjacent the metal/semiconductor interface after annealing is increased due to diffusion of the dopant material from the metal-dopant alloy into the semiconductor during annealing to provide a dopant rich semiconductor region in the substrate. The semiconductor substrate can be silicon. The metal of the metal-dopant alloy can be Ni. The dopant of the metal-dopant alloy can be Pb. A contact length of the MOSFET is associated with a technology node of 14 nm or less.

The concentration of dopant material in the semiconductor substrate directly adjacent the metal/semiconductor interface after annealing due to diffusion of the dopant material from the metal-dopant alloy into the semiconductor during annealing provides a dopant rich semiconductor region in the substrate having a dopant atom concentration of greater than 10²⁰ cm⁻³.

A method of producing an ultra low MOSFET external contact resistance (ρ_{C}) across metal/semiconductor interface includes depositing a metal-dopant alloy on a semiconductor substrate, and annealing the semiconductor substrate to temperature above which a dopant material of the metal dopant alloy diffuses from the metal-dopant alloy into the semiconductor substrate and creates a dopant-rich layer in the semiconductor substrate adjacent to a compound formed by reaction of the metal of the metal-dopant alloy during annealing, such that the external contact resistance ρ_{C} for the metal/semiconductor interface is below 1×10⁻⁸ ohm-cm². The depositing can be performed using a PVD (Physical Vapor Deposition) process and may use a RFPVD (Radio Frequency-enhanced Physical Vapor Deposition) process. The metal of the metal-dopant alloy may be selected from the group of Ni, Pd, and Pt. The dopant material of the metal-dopant alloy may be chosen from the group comprising P, As, and Sb. The annealing raises the temperature of the substrate to at least 400° C. The annealing temperature provides a diffusion rate of the dopant of the metal/dopant alloy that is substantially greater than the diffusion rate of the metal of the metal/dopant alloy. The external contact resistance _{Pc} for the metal/semiconductor interface may be below 4×10⁻⁹ ohm-cm².

### BRIEF DESCRIPTION OF THE DRAWINGS

The manner in which the above recited features embodiments can be understood in detail, a more particular description, briefly summarized above, may be had by reference to embodiments, some of which are illustrated in the appended drawings. It is to be noted, however, that the appended drawings illustrate only typical embodiments and are therefore not to be considered limiting of scope.

FIG. 1 is a schematic cross-section showing a transistor represented by three equivalent resistive elements.

FIGS. 2A, 2B, and 2C show the progressive steps of the process of depositing a metal-dopant alloy in a hole on a semiconductor substrate and annealing the structure to provide a high concentration dopant in the region of the substrate close to the deposited and annealed material.

FIG. 3 shows an alternate embodiment of a gate structure utilizing the apparatus and method as described herein.

FIG. 4 shows a plot of the contact length in nanometers versus the technology node in nanometers.

FIG. 5 shows a plot of the contact resistivity in Ohms-cm² versus active surface concentration in centimeters⁻³.

FIG. 6 shows a plot of the contact resistivity versus concentration of dopant atoms in semiconductor surface.

FIG. 7 shows the relative diffusivity exemplary metal and dopant materials used in an apparatus and method described herein.

### DETAILED DESCRIPTION

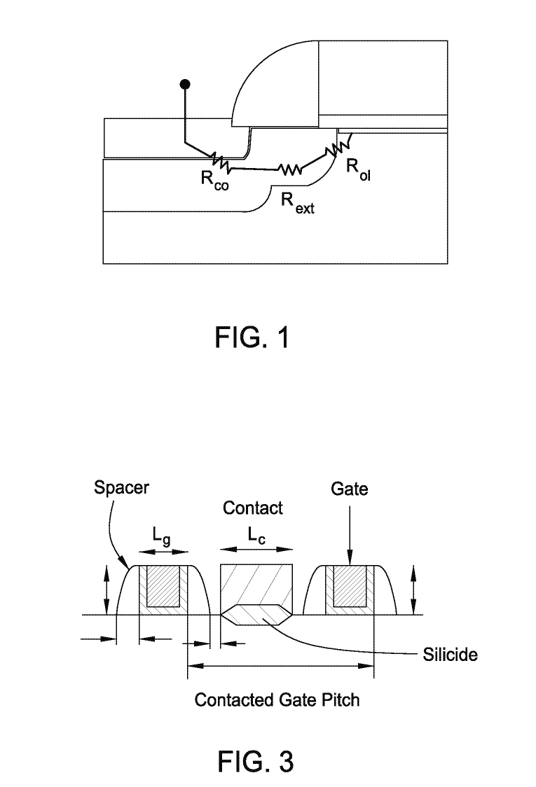

FIG. 1 is a schematic cross-section showing a transistor represented by three equivalent resistive elements. The R_{co} is the contact resistance, Rₑₓₜ the external resistance and Rₒₗ is the overlap resistance.

One of the remaining big challenges to solve is low constant resistance in order to realize high performance and low power CMOS chips. Nickel silicide (NiSi) and nickel platinum silicide (NiPtSi) on silicon are leading materials employed in advanced transistors today (baseline ρ_{C}≈1×10⁻⁸ ohm-cm²). However, ρ_{C} for this interface needs to be substantially reduced below 4×10⁻⁹ ohm-cm² for 14 nm node and beyond. To achieve this target, more innovative contact schemes are required that should drastically lower the Schottky barrier height (SBH) between metal and semiconductor S/D regions or increase the active doping level at the silicide/silicon interface. Here, the use of RFPVD method with a target Ni mixed with Sb. The deposited Ni—Sb metal on the silicon is then annealed to form silicide. The Sb will segregate at the silicide/silicon interface resulting in higher active surface doping concentration and lower contact resistivity. In other words, Sb lowers both R_{S/D} and ρ_{c} in the equation.

R_{C}=2×(ρ_{c}×R_{S/D}^{1/2}/[W_{C}tanh(L_{C}/L_{T})],

resulting in lower R_{c} for a given contact length (L_{C})

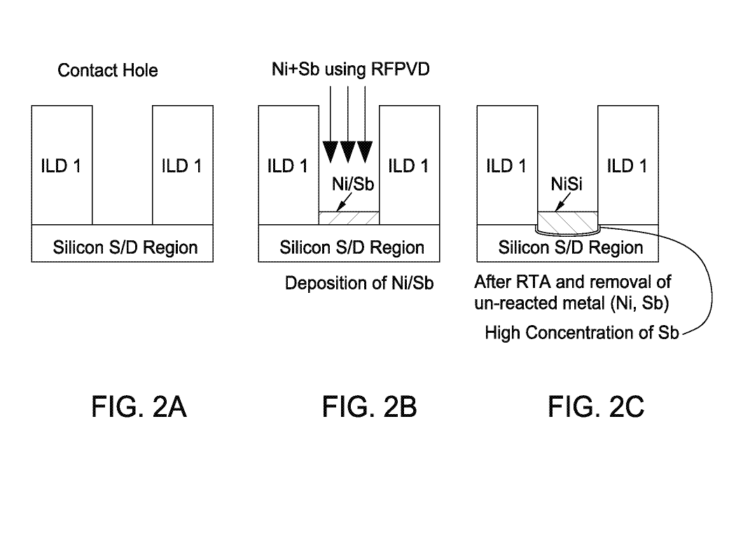

FIGS. 2A, 2B, and 2C show the progressive steps of the process of depositing a metal-dopant alloy in a hole on a semiconductor substrate and annealing the structure to provide a high concentration dopant in the region of the substrate close to the deposited and annealed material.

In FIG. 2, an interlayer dielectric has a contact hole between two walls leading to a silicon substrate region. Using a deposition mechanism such as PVD, the metal-dopant alloy such as nickel antimony is deposited as a layer of approximately 10 nm thickness in this contact hole. As seen in FIG. 20, after annealing the silicon substrate, nickel will have formed a silicide in the transition region and a region with a high concentration of antimony is located in the silicon adjacent to the nickel silicide.

FIG. 3 shows an alternate embodiment of a gate structure utilizing the apparatus and method as described herein. The dimensions shown here relate to the discussion of the factors which dictate the need to greatly reduce the contact resistance.

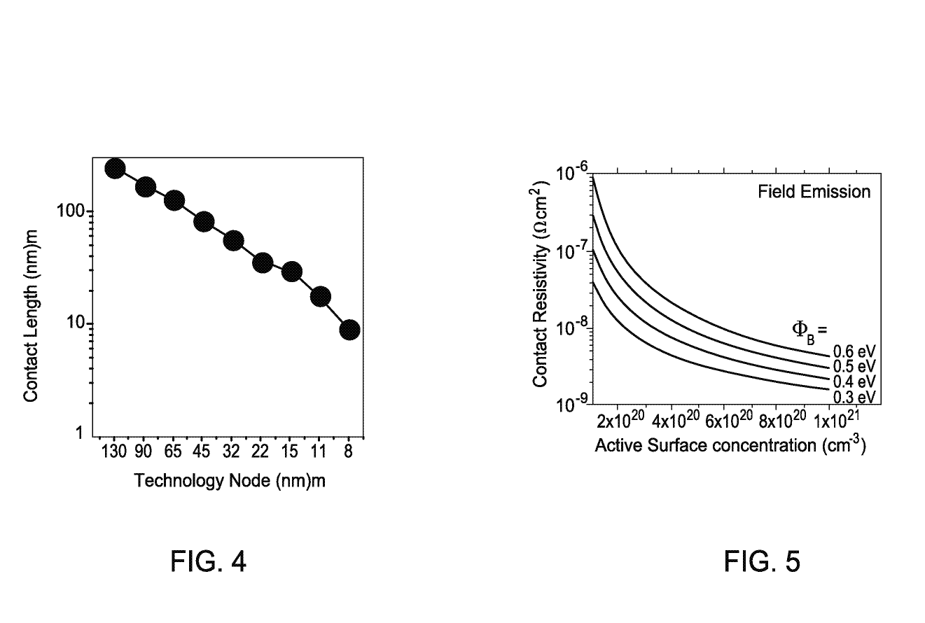

FIG. 4 shows a plot of the contact length in nanometers versus the technology node in nanometers. This plot presents the history of the dimensions of transistors on substrates to confirm the need for smaller and smaller nodes which as a result, without a change in process, would result in a higher and higher contact resistance.

FIG. 5 shows a plot of the contact resistivity in Ohms-cm² versus active surface concentration in centimeters⁻³. This plot illustrates the improved performance of a substrate when there is a high surface concentration of dopant material.

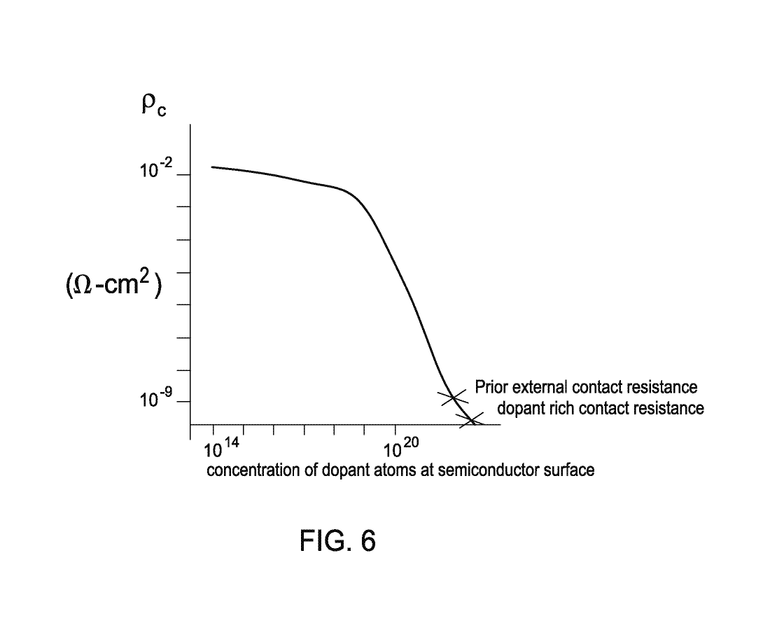

FIG. 6 shows a plot of the contact resistivity versus concentration of dopant atoms in the semiconductor surface. Illustrates the current state-of-the-art described as prior external contact resistance and the improvement achieved by utilizing an apparatus and method as described herein. Since the scale is a log scale the improvement is approximately one order of magnitude.

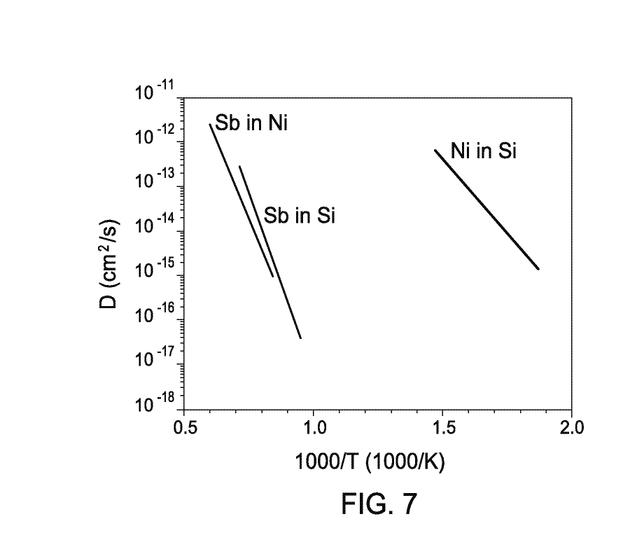

FIG. 7 shows the relative diffusivity exemplary of metal and dopant materials used in an apparatus and method described herein. This plot shows the high diffusivity of antimony in silicon and nickel which facilitates the diffusion of antimony into the silicon during the annealing of the deposited metal dopant alloy in the whole such that the antimony diffuses into the silicon layer and creates a high concentration of atoms to promote conduction and reduce contact resistivity.

In the prior art, nickel is deposited instead of nickel alloyed with antimony. By adding antimony, the antimony diffuses during the thermal anneal, resulting in very high concentration of antimony that diffuses out of the nickel into the semiconductor and becomes very highly concentrated up top.

During the RTA (rapid thermal anneal) there is a change in the location of the interface and the antimony in the metal-dopant alloy will diffuse into the silicon.

Thermal annealing, preferably takes place at about 400° C.

The nickel reacts with the silicon to form a nickel silicide.

The diffusion actually changes the composition.

The region at the bottom of the annealed section under the nickel silicide is an antimony-rich region that has a thickness in the nanometer range of about 1 nm to 10 nm.

RFPVD is used to achieve good bottom coverage of the contact hole. The interface, does not really move, what happens is that is that there is diffusion.

While the foregoing is directed to embodiments of the present invention, other and further embodiments of the invention may be devised without departing from the basic scope thereof, and the scope thereof is determined by the claims that follow.

1. A transistor with an electrical contact across a metal/semiconductor interface, comprising:
a first semiconductor substrate upon which a metal-dopant alloy layer has been deposited and annealed, wherein a metal of the metal-dopant alloy is chosen from a group comprising Ni, Pd, and Pt and a dopant in the metal-dopant alloy is chosen from a group comprising P, As, and Sb; and
a concentration of the dopant in the first semiconductor substrate directly adjacent to an interface with the metal-dopant alloy layer provides a dopant-rich semiconductor region in the first semiconductor substrate after annealing due to diffusion of the dopant from the metal-dopant alloy into the first semiconductor substrate during annealing.

2. The transistor of claim 1, wherein the first semiconductor substrate is silicon.

3. The transistor of claim 1, wherein the metal is Ni.

4. The transistor of claim 1, wherein the dopant is Pb.

5. The transistor of claim 1, wherein a contact length of the transistor is equal to the contact length of a transistor at a technology node of 14 nm or less.

6. The transistor of claim 1, wherein the concentration of dopant directly adjacent to the interface provides a dopant-rich semiconductor region in the first semiconductor substrate, the dopant-rich semiconductor region having a dopant atom concentration of greater than 10²⁰ cm⁻³ after annealing.

7. A method of fabricating a transistor with an ultra low external contact resistance across a metal/semiconductor interface comprising steps of:
depositing a metal-dopant alloy on a semiconductor substrate to form an interface between the metal-dopant alloy and the semiconductor substrate;
annealing the semiconductor substrate to temperature above which a dopant material of the metal-dopant alloy diffuses into the semiconductor substrate and forms a dopant-rich layer in the semiconductor substrate adjacent to a layer formed by reaction of a metal of the metal-dopant alloy with the semiconductor substrate during annealing, such that an external contact resistance across the metal/semiconductor interface is below 1×10⁻⁸ ohm-cm².

8. The method of claim 7, wherein depositing is performed using a physical vapor deposition process.

9. The method of claim 7, wherein depositing is performed using a radio frequency-enhanced physical vapor deposition process.

10. The method of claim 7, wherein the metal is selected from a group comprising Ni, Pd, and Pt.

11. The method of claim 10, wherein the dopant material is selected from a group comprising P, As, and Sb.

12. The method of claim 7, wherein the dopant material is selected from a group comprising P, As, and Sb.

13. The method of claim 7, wherein annealing raises the temperature of the substrate to at least 400° C.

14. The method of claim 7, wherein the diffusion rate of the dopant material is substantially greater than the diffusion rate of the metal at the annealing temperature.

15. The method of claim 7, wherein the external contact resistance the interface is below 4×10⁻⁹ ohm-cm² after annealing.

16. The method of claim 7, wherein the metal-dopant alloy is deposited at the bottom of a contact hole.

17. The method of claim 7, wherein the metal is selected from a group comprising P, As, and Sb, the dopant material is selected from a group comprising P, As, and Sb, depositing is performed using a physical vapor deposition process, annealing raises the temperature of the substrate to at least 400° C., the diffusion rate of the dopant material is substantially greater than the diffusion rate of the metal at the annealing temperature, the external contact resistance of the interface is below 4×10⁻⁹ ohm-cm² after annealing, and the metal-dopant alloy is deposited at the bottom of a contact hole.

18. The method of claim 17, wherein the physical vapor deposition process is a radio frequency-enhanced physical vapor deposition process.

19. The transistor of claim 1, wherein the first semiconductor substrate is silicon, the metal is Ni, the dopant is Sb, and the concentration of dopant material directly adjacent to the interface provides a dopant-rich semiconductor region in the first semiconductor substrate with a dopant atom concentration of greater than 10²⁰ cm⁻³ after an annealing process.

20. The transistor of claim 19, wherein a contact length of the transistor is equal to the contact length of a transistor at a technology node of 14 nm or less.
